(19) United States
(12) Patent Application Publication
(10) Pub. No.: US 2007/0090419 A1
(43) Pub. Date: Apr. 26, 2007

(54) CMOS image sensor and manufacturing method thereof

(76) Inventor: Jun Seok Lee, Goyang-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/585,539

(22) Filed: Oct. 24, 2006

(30) Foreign Application Priority Data
Oct. 24, 2005 (KR) 10-2005-0100201

(51) Int. Cl. H01L 31/113; H01L 31/06; H01L 31/062; H01L 21/8242

(52) U.S. Cl. 257/290; 257/462; 438/241

(57) ABSTRACT

A CMOS image sensor and a method for manufacturing the same are provided. The CMOS image sensor includes: a photo diode formed in a semiconductor substrate for generating an optical signal from incident light; a first micro lens formed on the semiconductor substrate above the photo diode; a plurality of inter-layer dielectrics and metal wires formed on the semiconductor substrate having the first micro lens; a planarization layer formed above the plurality of inter-layer dielectrics metal wires; and a second micro lens formed on the planarization layer. In one embodiment, the second micro lens incorporates a fly-eye pattern.

### RELATED APPLICATION(S)

This application claims the benefit, under 35 U.S.C. §119(e), of Korean Patent Application Number 10-2005-0100201 filed Oct. 24, 2005, which is incorporated herein by reference in its entirety.

### FIELD OF THE INVENTION

The present invention relates to an image sensor.

### BACKGROUND OF THE INVENTION

In general, image sensors are semiconductor devices that transform an optical image to electrical signals. The CMOS image sensor is a device that employs a switching mode to sequentially detect an output of each unit pixel by means of MOS transistors using control circuits and signal-processing circuits. Each unit pixel incorporates a photodiode.

In making such various image sensors, efforts are being made to improve the photosensitivity of the image sensor.

For example, the CMOS image sensor is composed of a photo diode for sensing light and a CMOS logic circuit for processing the sensed light into electric signals. For better photosensitivity, two methods have been proposed. In a first method, efforts are used to increase the photo diode area with respect to the total area of the image sensor. In a second method, technologies are used to reduce an incident path of light, to form a micro lens at an upper portion thereof, and to receive more light in a photo diode region.

FIG. 1 is a view showing a CMOS image sensor having a photo diode arrangement according to the related art.

As shown in FIG. 1, a photo diode 32 is formed by selectively implanting impurity ions in the semiconductor substrate 31, and functions to sense red (R), green (G), and blue (B) signals.

Moreover, a first inter-layer dielectric 33 is formed on the semiconductor substrate 31. First metal wires 34 are spaced apart from each other on the first inter-layer dielectric 33. A second inter-layer dielectric 35 is formed at an entire surface of the semiconductor substrate 31 having the first metal wire 34. Second metal wires 36 are spaced apart from each other on the second inter-layer dielectric 35. A third inter-layer dielectric 37 is formed on the semiconductor substrate 31 having the second metal wire 36. Third metal wires 38 are spaced apart from each other on the third inter-layer dielectric 37. A planarization layer 39 is formed on the third metal wires 37. A micro lens 40 is formed on the planarization 39, and receives light.

In the CMOS image sensor according to the related art having a construction mentioned previously, the microlens 40 is formed by coating a sensitive polymer on the planarization layer 39, selectively patterning the resulting object by exposure and development processes, and performing a thermal process thereof.

At this time, in general, so as to embody a curvature radius of the micro lens 40, after the sensitive polymer is developed, it is thermally reflowed in a cure baking stage to change the sensitive polymer to a curved shape.

As described above, when light is irradiated to a surface of the micro lens 40 in the completed CMOS image sensor according to the related art, the light is refracted at different angles along a curved surface of the lens. Here, the refracted lights pass through a plurality of inter-layer dielectrics and reach the photo diode 32.

However, there may be a predetermined number of lights among the light refracted by the micro lens 40, which do not reach the photo diode 32 according to refraction angles thereof. These lights that do not reach photodiode 32 deteriorate a function of the image sensor.

That is, there is a slight possibility of lights being dispersed widely by the micro lens 40 before reaching the photo diode 32. Moreover, noise from the dispersed lights occurs in an adjacent photo diode.

### SUMMARY OF THE INVENTION

Accordingly, the present invention is directed to a CMOS image sensor and a method for manufacturing the same that addresses and/or substantially obviates one or more problems, limitations, and/or disadvantages of the related art.

An object of many embodiments of the present invention is to provide a CMOS image sensor and a method for manufacturing the same, which can prevent or substantially reduce a dispersion of light being incident to a photo diode through a micro lens.

Another object of many embodiments of the present invention is to provide a CMOS image sensor capable of improving a performance of a device by securing uniformity of incident light.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a CMOS (complementary metal oxide silicon) image sensor comprising: a photo diode formed in a semiconductor substrate for generating an optical signal from incident light; a first micro lens formed on the semiconductor substrate; a plurality of inter-layer dielectrics and metal wires formed on the semiconductor substrate having the first micro lens; a planarization layer formed above the plurality inter-layer dielectrics and metal wires; and a second micro lens formed on the planarization layer.

In another aspect of the present invention, there is provided a method for manufacturing a CMOS (complementary metal oxide silicon) image sensor comprising: (i) forming a photo diode in a semiconductor substrate; (ii) forming a first micro lens above the photo diode; (iii) forming an inter-layer dielectric and a metal wire on the semiconductor substrate having the first micro lens; (iv) forming a planarization layer above the inter-layer dielectric and the metal wire; and (v) forming a second micro lens on the planarization layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a view showing a CMOS image sensor according to the related art;

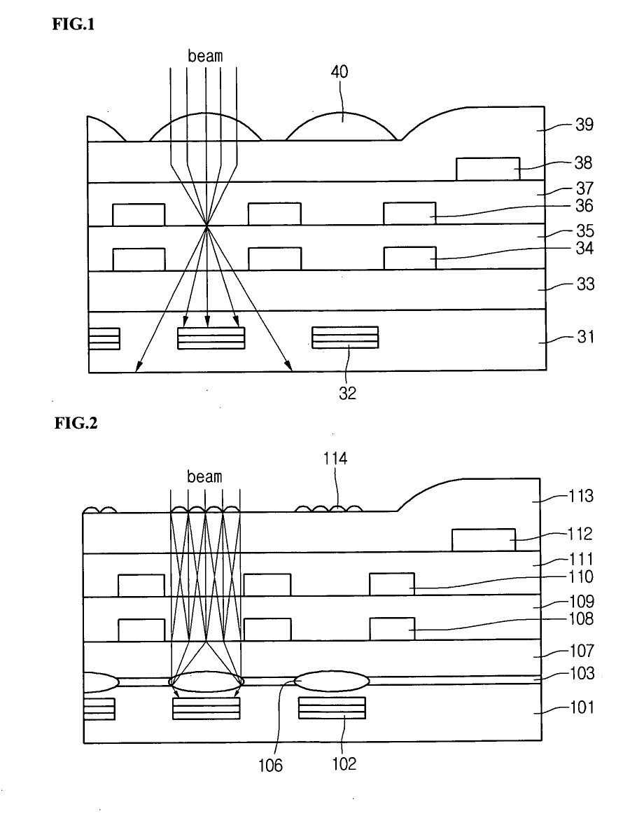

FIG. 2 is a cross-sectional view of a CMOS image sensor according to an embodiment of the present invention; and

FIGS. 3 through 9 are cross-sectional views of a CMOS image sensor for describing a method for manufacturing a CMOS image sensor according to an embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

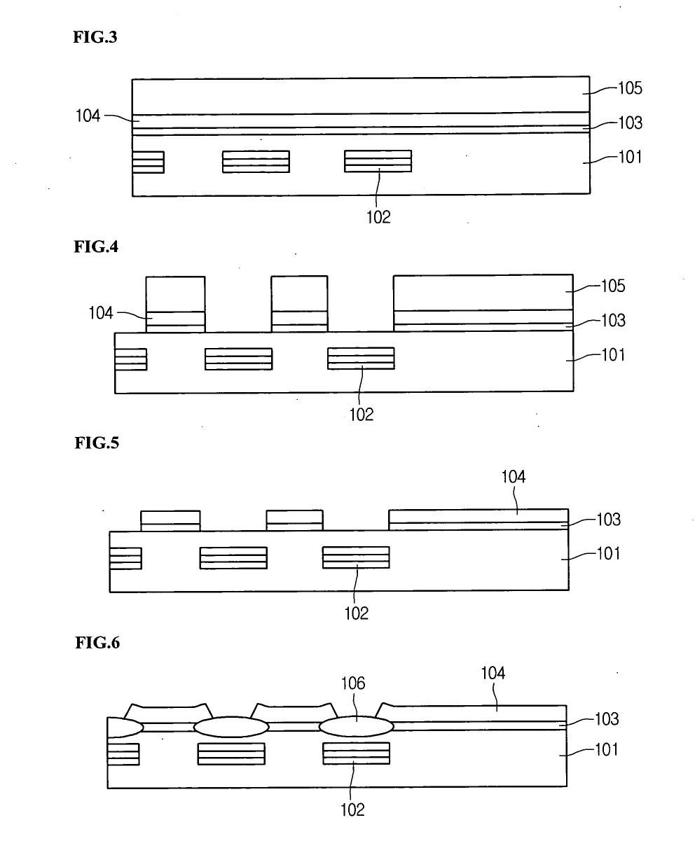

FIG. 2 is a cross-sectional view of a CMOS image sensor according to an embodiment of the present invention.

With reference to FIG. 2, a photo diode 102 can be formed in a substrate 101, and an oxide film 103 can be formed on the semiconductor substrate 101 including photodiode 102.

In one embodiment, the photo diode 102 can be formed to sense red (R), green (G), and blue (B) signals according to a wavelength of incident light.

A first micro lens 106 can be formed above the photo diode 102. The first micro lens 106 can be formed interposed in a part of the oxide film 103. That is, the first micro lens 106 can be formed to penetrate part of the oxide film.

A first inter-layer dielectric 107, a first metal wire 108, a second inter-layer dielectric 109, a second metal wire 110, a third inter-layer dielectric 111, a third metal wire 112, and a planarization layer 113 can be sequentially formed on the oxide film 103.

The second micro lens 114 can be formed on the planarization layer 113 at a position corresponding to each photo diode 102. In a specific embodiment, the second micro lens 114 can have a fly-eye lens (FEL) or moth-eye lens pattern.

In a CMOS image sensor having a construction as shown in FIG. 2, when incident light is irradiated to a surface of the second micro lens 114, the second micro lens 114 can function as a FEL, and a separate lens (not shown) can be used to transmit incident zero order light to the second microlens 114 and provide uniform optical distribution by the coupling of the lights.

The first micro lens 106 can be formed at a path of the incident light between the second micro lens 114 and the photo diode 102, so that the incident light can be collected in the photo diode 102 through the micro lens 106.

Moreover, the first and second metal wires 108 and 111 can be formed such that the first and metal wires 108 and 111 are not located on the region of the photo diode. The first and second metal wires 108 and 11 can be formed to intercept a separated light dispersion in respective metal wire parts.

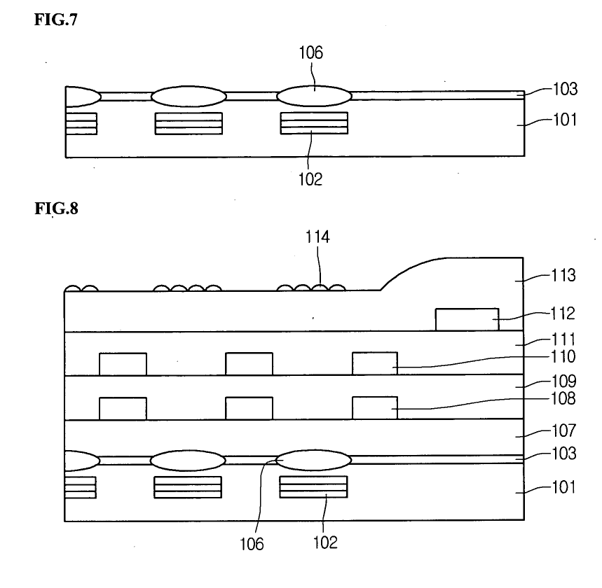

FIGS. 3 through 9 are cross-sectional views of a CMOS image sensor for describing a method for manufacturing a CMOS image sensor according to an embodiment of the present invention.

First, as shown in FIG. 3, impurity ions can be selectively implanted in the semiconductor substrate 101 to form photo diodes, which sense an optical signal from incident light.

Here, the photo diodes 102 can be formed of impurities implanted to different depths. According to the implanted depths, photo diodes can be formed for sensing red, green, and blue signals, respectively.

In one embodiment, a red photo diode can be formed at the deepest position with a green photo diode and a blue photo diode sequentially formed on the red photo diode.

In a specific embodiment, the red photo diode may be formed in a surface of the semiconductor substrate 101 having a first predetermined depth, the green photo diode may be formed in a surface of a first epitaxial layer having a second predetermined depth. The first epitaxial layer can be formed by a first epitaxial process of the semiconductor substrate 101.

In a further embodiment, the blue photo diode can be formed in a surface of a second epitaxial layer having a third predetermined depth. The second epitaxial layer can be formed on the first epitaxial layer by a second epitaxial process of the semiconductor substrate 101.

Next, an oxide film 103 and a nitride film 104 can be sequentially formed on an entire surface of the semiconductor substrate 101 on which the photo diode 102 is formed.

In addition, a photoresist 105 can be coated on the nitride film 104.

Referring to FIG. 4, the photoresist 105 can be selectively patterned to expose the oxide film 103 and the nitride film 104 above the photo diodes 102.

Then, by using the photoresist 105 as an etch mask, parts of the nitride film 104 and the oxide film 103 can be etched to expose the semiconductor substrate 101 at the upper side of the photo diode 102.

Referring to FIG. 5, the photoresist 105 can be removed, leaving the remaining portions of the nitride film 104 and the oxide film 103.

Referring to FIG. 6, using the nitride film 104 and the oxide film 103 as mask, silicon Si of the exposed semiconductor substrate 101 can be grown by, for example, an epitaxial process. The silicon growth results in the growth of the first micro lens 106 at an upper side of each photo diode 102.

In one embodiment, the first microlens 106 is formed in an elliptical shape between the edges of the oxide layer 103, and a predetermined part of the nitride film 104 is transformed in a bird's beak pattern.

More particularly, the nitride film 104 can function to control a partial growth of the silicon on the semiconductor substrate 101, thereby causing the grown silicon to have an ellipsoidal micro lens shape.

Accordingly, the first micro lens 106 can have a shape in which the thickness thereof becomes gradually thicker as it goes from the edge thereof toward the center thereof.

Referring to FIG. 7, the nitride film 104 can be removed, and a thermal oxidation can then be performed on the semiconductor substrate 101.

Referring to FIG. 8, a first inter-layer dielectric 107, a first metal wire 108, a second inter-layer dielectric 109, a second metal wire 110, a third inter-layer dielectric 111, and a third metal wire 112 can be sequentially formed on the semiconductor substrate 101 having the first micro lens 106.

A planarization layer 113 can be formed on an entire surface of the semiconductor substrate 101 having the third metal wire 112.

Then, a photoresist can be coated on the planarization layer 113 and patterned by performing exposure and development processes to form a photoresist pattern. In one embodiment, the photoresist pattern can be used to form a FEL pattern. In a specific embodiment, the photoresist pattern forms a microlens pattern where the photoresist for one microlens part of the second microlens 114 has a size 25% smaller than the first micro lens 106.

Next, the photoresist pattern can be thermally flown to form a second micro lens 114. In a specific embodiment, reflowing the photoresist creates a microlens 114 having the FEL pattern.

Here, the second micro lens 114 can be formed at a position corresponding to the first micro lens 106, that is, above the first micro lens 106.

Accordingly, light being incident through the second micro lens 114 is primarily concentrated and moved to the first micro lens 106. Furthermore, light incident to the first micro lens 106 is secondarily concentrated and is incident to a photo diode 102, which is positioned below the first micro lens 106.

The first micro lens 106 and the second micro lens 114 can be formed above the photo diode 102 for more precision in bringing the light incident an image sensor incident to the photo diode and preventing the interference between adjacent photo diodes.

It will be apparent to those skilled in the art that various modifications and variations can be made in the present invention. Thus, it is intended that the present invention covers the modifications and variations of this invention provided they come within the scope of the appended claims and their equivalents.

I claim:

1. A CMOS (complementary metal oxide silicon) image sensor comprising:
a photo diode formed in a semiconductor substrate for generating an optical signal from incident light;
a first micro lens formed on the semiconductor substrate above the photodiode;
a plurality of inter-layer dielectrics and metal layers formed on the semiconductor substrate having the first micro lens;
a planarization layer formed above the plurality of inter-layer dielectrics and metal layers; and
a second micro lens formed on the planarization layer.

2. The CMOS image sensor according to claim 1, wherein the first micro lens is grown from the semiconductor substrate.

3. The CMOS image sensor according to claim 1, wherein the first micro lens is disposed between the second micro lens and the photo diode.

4. The CMOS image sensor according to claim 3, wherein the second microlens has a fly-eye lens pattern.

5. The CMOS image sensor according to claim 1, wherein light being incident to the second micro lens reaches the photo diode through the first micro lens.

6. The CMOS image sensor according to claim 1, further comprising an oxide film formed on the semiconductor substrate, wherein the first micro lens is formed to penetrate a predetermined part of the oxide film.

7. The CMOS image sensor according to claim 1, wherein the first micro lens has a shape in which the thickness thereof becomes gradually thicker as it goes from the edge thereof toward the center thereof.

8. A CMOS (complementary metal oxide silicon) image sensor comprising:
a semiconductor substrate;
a photo diode in the semiconductor substrate for generating an optical signal from incident light;
an inter-layer dielectric on the semiconductor substrate;
a first micro lens formed between the photo diode and the inter-layer dielectric;
a metal wire formed on the inter-layer dielectric;
a planarization layer formed on the metal wire; and
a second micro lens formed on the planarization layer.

9. The CMOS image sensor according to claim 8, wherein the first micro lens is formed at a path of incident light between the second micro lens and the photo diode.

10. The CMOS image sensor according to claim 8, further comprising an oxide film formed at a side of the first micro lens.

11. The CMOS image sensor according to claim 8, wherein the second micro lens comprises a fly-eye pattern.

12. A method for manufacturing a CMOS (complementary metal oxide silicon) image sensor comprising:
forming a photo diode in a semiconductor substrate;
forming a first micro lens at an upper side of the photo diode;
forming an inter-layer dielectric and a metal wire on the semiconductor substrate having the first micro lens;
forming a planarization layer above the inter-layer dielectric and the metal wire; and
forming a second micro lens on the planarization layer.

13. The method according to claim 12, further comprising forming an oxide film on the semiconductor substrate prior to forming a first microlens at an upper side of the photo diode.

14. The method according to claim 12, wherein forming the first micro lens comprises growing a part of the semiconductor substrate.

15. The method according to claim 12, wherein forming the first microlens at an upper side of the photo diode comprises:
sequentially forming an oxide film and a nitride film on the semiconductor substrate;
selectively etching predetermined regions of the oxide film and the nitride film to expose the semiconductor substrate; and
growing a part of the semiconductor substrate at the exposed semiconductor substrate.

16. The method according to claim 15, wherein the predetermined regions are located above the photo diode.

17. The method according to claim 15, further comprising removing the nitride film after growing the part of the semiconductor substrate.

18. The method according to claim 12, further comprising:
forming a second inter-layer dielectric on the metal wire; and
forming a second metal wire on the second inter-layer dielectric, wherein the planarization layer is formed above the second inter-layer dielectric and second metal wire.
